(19) United States
(12) Patent Application Publication
(10) Pub. No.: US 2005/0276024 A1
(43) Pub. Date: Dec. 15, 2005

(54) Flexi-rigid printed circuit board with integral flexible heat sink area

(76) Inventor: Steven Dale Westbury, Devon (GB)

Correspondence Address: NIXON & VANDERHYE, PC, 901 NORTH GLEBE ROAD, 11TH FLOOR, ARLINGTON, VA, 22203, US

(21) Appl. No.: 10/501,093

(22) PCT Filed: Jun. 10, 2004
(86) PCT No.: PCT/GB04/02452

§ 371 Date: Jul. 9, 2004

(51) Int. Cl. H05K 1/00

(52) U.S. Cl. 361/749; 174/50

(57) ABSTRACT

A flexi-rigid printed circuit board has a rigid area made up of inner layers of flexible copper and outer layers of rigid insulating material. The board includes an integral flexible heat sink area having springy edge regions of exposed flexible copper layers without outer layers of rigid insulating material, and a metal heat conducting body which is springily engaged for the rigid areas of the board.

This invention relates to a flexi-rigid printed circuit board with integral flexible heat sink area.

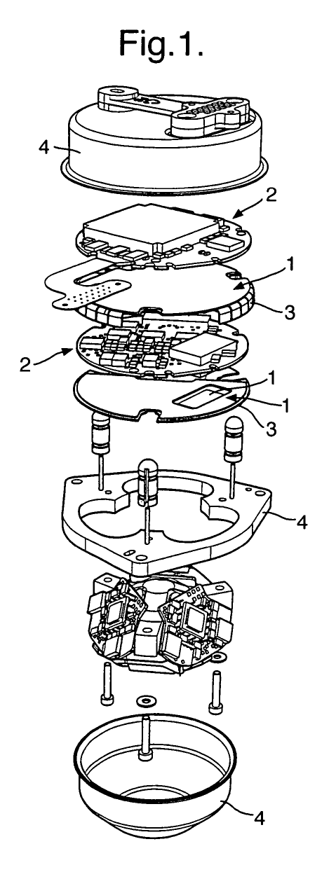

Conventionally heat is conducted away from key electronic components in a confined area of a printed circuit board by using a soft thermal interface material 1 sandwiched between the electronic components 2 and an aluminium heat spreader 3 as shown in FIG. 1 of the accompanying drawings. The soft thermal interface material 1 is used to conform to the electronic component skyline and transfer heat to the aluminium heat spreader 3 from which this heat is then transferred to the external body components 4 of the assembly. This conventional assembly is not cost effective as it requires additional components such as the interface material 1 and aluminium heat spreader 3 which additionally add weight and space requirement to the assembly as well as cost.

There is thus a need for a simpler and more cost effective system for conducting heat away from key electronic components on a printed circuit board in a confined area.

According to a first aspect of the present invention there is provided a flexi-rigid printed circuit board having a rigid area, made up of inner layers of flexible copper and outer layers of rigid insulating material, and an integral flexible heat sink area having springy edge regions of exposed flexible copper layers without outer layers of rigid insulating material, and a metal heat conducting body which is springily engaged by the edge regions to provide a heat sink for the rigid areas of the board.

Preferably the exposed flexible copper layers of the springy edge regions are at least partially coated with an anticorrosive material, more preferably at least one of tin, lead, gold.

Conveniently the board includes tubular metal thermal vias interconnecting flexible copper layers in the rigid area to improve heat transfer through the flexible copper layers.

Advantageously at least some of the thermal vias are located in the rigid area below parts where high heat output components are to be mounted.

Preferably the metal heat conduction body is a shell into which the heat sink area is a push fit and held in place by spring contact between the springy edge regions and the shell.

Conveniently the springy edge regions are in the form of tabs extending from the rigid area.

For a better understanding of the present invention and to show how the same may be carried into effect, reference will now be made to the accompanying drawings, in which;

FIG. 1 is a perspective exploded view of a conventional printed circuit board assembly with a heat conduction system not according to the present invention,

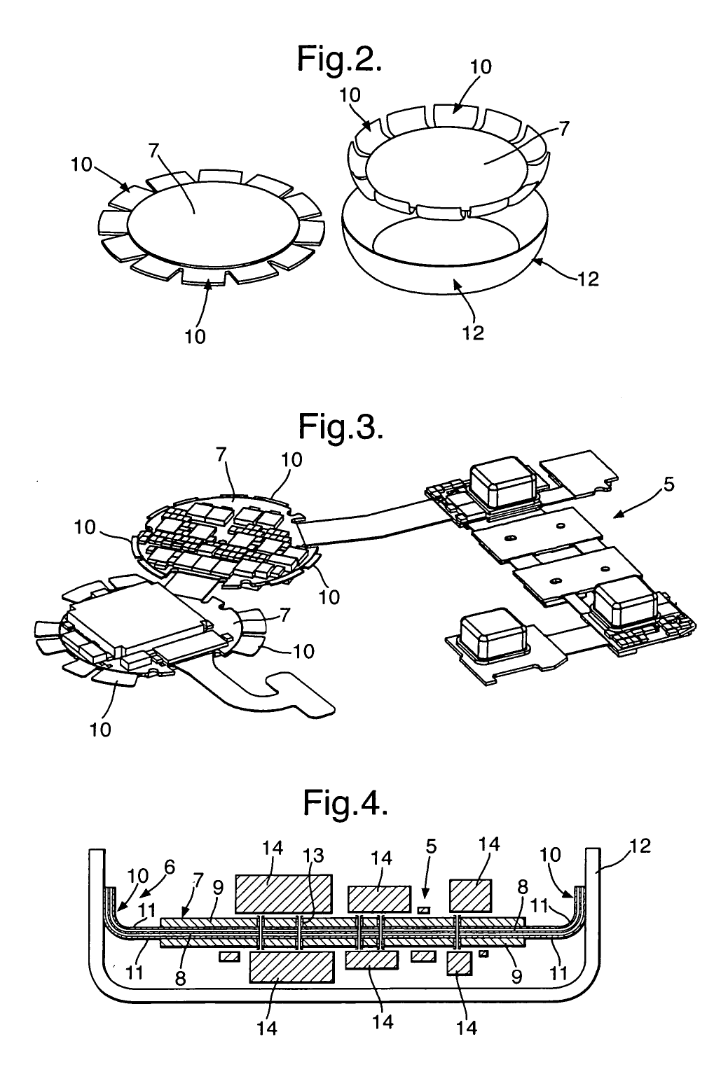

FIG. 2 is a diagrammatic perspective view of a flexible heat sink area with heat conducting body according to the present invention,

FIG. 3 is a perspective view of part of a flexi-rigid printed circuit board according to the present invention,

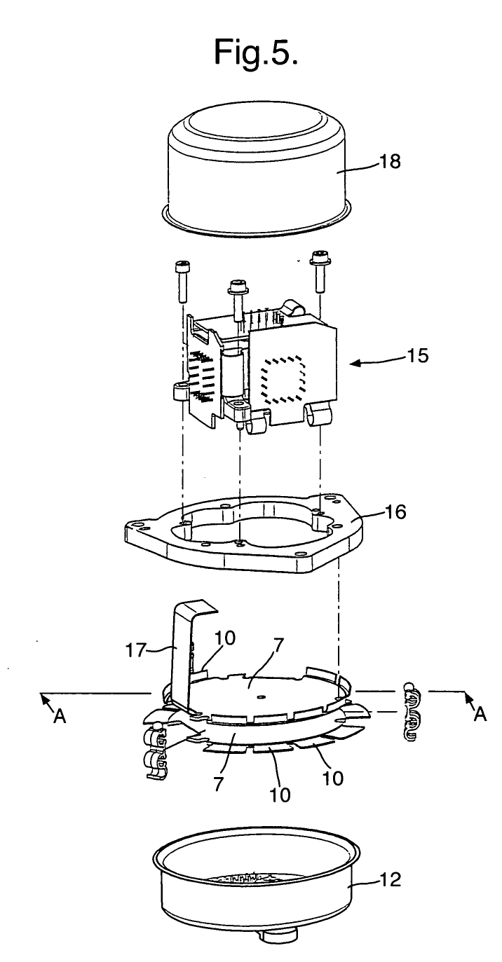

FIG. 4 is a cross-sectional view of an assembled flexi-rigid printed circuit board according to the present invention taken through an assembled flexi-rigid printed circuit board along the line A-A of FIG. 5, and

FIG. 5 is a perspective exploded view of a flexi-rigid printed circuit board according to the present invention forming part of an assembly.

A flexi-rigid printed circuit board 5 with integral flexible heat sink indicated generally at 6 according to the present invention is shown in FIGS. 2 to 5 of the accompanying drawings. The flexi-rigid printed circuit board 5 has at least one rigid area 7 made up of inner layers 8 of flexible copper as can best be seen from FIG. 4 and outer layers 9 of rigid insulating material. The board 5 includes an integral flexible heat sink area having springy edge regions 10 of exposed flexible copper layers 11 without the outer layers 9 of rigid insulating material.

Also forming part of the integral flexible heat sink area is a metal heat conducting body 12 preferably in the form of a shell as illustrated in FIGS. 4 and 5. As can be seen specifically from FIG. 4 the body 12 is springily engaged by the edge regions 10 to provide a heat sink for the rigid areas 7 of the printed circuit board 5. As can be seen more clearly from FIG. 4, the heat sink area 7 is a push fit into the shell 12 and is held in place by spring contact between the springy edge regions 10 and the inner wall of the body 12.

Preferably the springy edge regions 10, as can be seen from the three stage drawing of FIG. 2, are in the form of tabs extending from the rigid area 7. These tabs can be bent upwardly out of the plane of the rigid area 7 as can be seen on the top right hand of FIG. 2 and eventually are butted together as shown in the bottom right portion of FIG. 2 to provide effectively a circular form as shown in cross-section in FIG. 4. It is to be understood, however, that although the rigid area 7 has been illustrated as basically circular in plan with the springy edge regions 10 extending radially as tabs therefrom and with the body 12 having a tubular format, any other shape of rigid area 7, springy edge regions 10 and body 12 desired can be provided and utilised.

The springy edge regions 10 which effectively form extensions to the rigid area 7 are in the form of the exposed copper layers which extend integrally and as part of the inner layers 8 of flexible copper within the rigid area 7. Preferably the exposed layers of flexible copper which form the springy edge regions 10 are at least partially coated with anti corrosion material such as tin, lead and/or gold, for conductivity and corrosion resistance purposes. Thus the heat conducting layer provided by the inner layers of heat flexible copper runs into the rigid area 7 wherever it can and as many layers as possible are joined with thermal vias 13 as shown in FIG. 4. These thermal vias are conveniently tubular metal thermal vias which interconnect the flexible copper layers 8 in the rigid area 7 to improve heat transfer between the flexible copper layers. At least some of the thermal vias 13, as shown in FIG. 4, are located in the rigid area 7 below parts where high heat output components 14 are to be mounted.

The invention thus requires fewer components than the conventional solution described in respect of FIG. 1, requires no additional assembly time and has minimal extra space requirements as the flexible heat sink is very thin. This can be seen by a comparison between the conventional FIG. 1 assembly and the assembly of FIG. 5 which incorporates a flexi-rigid printed circuit board according to the present invention. In the illustration of FIG. 5 the rigid area 7 of the flexi-rigid printed circuit board has been shown without electrical components 15 for convenience. The electrical components 15 are nested together and secured to the rigid area 7 and springy edge regions 10 by means of a mounting plate 16 and connecting strap 17. A further casing cover 18 is provided for the assembly to cover the components 15.

1. A flexi-rigid printed circuit board having a rigid area, made up of inner layers of flexible copper and outer layers of rigid insulating material, and an integral flexible heat sink area having springy edge regions of exposed flexible copper layers without outer layers of rigid insulating material, and a metal heat conducting body which is springily engaged by the edge regions to provide a heat sink for the rigid areas of the board.

2. A flexi-rigid printed circuit board according to claim 1, wherein the exposed flexible copper layers of the springy edge regions are at least partially coated with an anti corrosion material.

3. A flexi-rigid circuit board according to claim 2, wherein the anti corrosion material is at least one of tin, lead, gold.

4. A flexi-rigid printed circuit board according to claim 1, including tubular metal thermal vias inter-connecting flexible copper layers in the rigid area to improve heat transfer between the flexible copper layers.

5. A flexi-rigid printed circuit board according to claim 4, in which at least some of the thermal vias are located in the rigid area below parts where high heat output components are to be mounted.

6. A flexi-rigid printed circuit board according to claim 1, wherein the metal heat conducting body is a shell into which the heat sink area is a push fit and held in place by spring contact between the springy edge regions and the shell.

7. A flexi-rigid printed circuit board according to claim 1, wherein the springy edge regions are in the form of tabs extending from the rigid area.

8. (canceled)
